(19) United States
(12) Patent Application Publication
(10) Pub. No.: US 2025/0176329 A1
(43) Pub. Date: May 29, 2025

(54) DISPLAY DEVICE

(71) Applicant: LG Display Co., Ltd., Seoul (KR)

(72) Inventors: SangBin LEE, Paju-si (KR); YoungSik KIM, Paju-si (KR); SungJin PARK, Paju-si (KR)

(73) Assignee: LG Display Co., Ltd., Seoul (KR)

(21) Appl. No.: 18/754,607

(22) Filed: Jun. 26, 2024

(30) Foreign Application Priority Data
Nov. 28, 2023 (KR) 10-2023-0168132

(51) Int. Cl. H01L 33/56; H01L 25/075; H01L 33/38; H01L 33/54

(52) U.S. Cl. CPC H10H 20/854; H01L 25/0753; H10H 20/8312; H10H 20/853

(57) ABSTRACT

A display device may include a substrate, a hole area, a display area surrounding the hole area, a light emitting device disposed in the display area on the substrate, a plurality of encapsulation layers disposed on the light emitting device, and a first dam and a second dam disposed in the hole area on the substrate. The first dam and the second dam may be spaced apart from each other. The light emitting device may include a first electrode disposed on the substrate, a light emitting layer disposed on the first electrode, and a second electrode disposed on the light emitting layer. An end of the second electrode may overlap the encapsulation layer and may be spaced apart from the first dam and the second dam.

### CROSS-REFERENCE TO RELATED APPLICATIONS

This application claims the benefit of and priority to Korean Patent Application No. 10-2023-0168132 filed on Nov. 28, 2023, the entirety of which is incorporated herein by reference for all purposes as if fully set forth herein.

### BACKGROUND

### 1. Field of the Invention

The present disclosure relates to an apparatus, and particularly to, for example, without limitation, a display device.

### 2. Description of the Related Art

A display device is widely used as a display screen of a notebook computer, a tablet computer, a smart phone, a portable display device, and a portable information device in addition to a display screen of a television or a monitor. With the advancement of technology, the display device may provide photographing or various sensing functions in addition to an image display function. Accordingly, the display device needs to include an electronic device such as a camera or a sensor.

Recently, research has been conducted on a hole-in-active area (HiAA) type display device in which a hole is formed in a display area, and the electronic device is disposed below the hole.

The description of the related art should not be assumed to be prior art merely because it is mentioned in or associated with this section. The description of the related art may include information that describes one or more aspects of the subject technology, and the description in this section does not limit the invention.

### SUMMARY

The inventors have recognized the problems and disadvantages of the related art, including the above problems, have performed extensive research and experiments, and have developed a new invention.

One or more aspects of the present disclosure are directed to providing a display with minimal moisture penetration.

Other aspects, features and advantages of the present disclosure are set forth in the present disclosure and will also be apparent from the present disclosure or may be learned by practice of the inventive concepts provided herein. Other aspects, features and advantages of the present disclosure may be realized and attained by the descriptions provided in the present disclosure, including the claims and the drawings.

To achieve these and other advantages and aspects of the present disclosure, in one or more aspects, a display device may include a substrate, a hole area and a display area surrounding the hole area, a light emitting device disposed in the display area on the substrate, a plurality of encapsulation layers disposed on the light emitting device, and a first dam and a second dam disposed in the hole area on the substrate. The first dam and the second dam may be spaced apart from each other. The light emitting device may include a first electrode disposed on the substrate, a light emitting layer disposed on the first electrode, and a second electrode disposed on the light emitting layer. An end of the second electrode may overlap the encapsulation layer and may be spaced apart from the first dam and the second dam.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure.

FIG. 1 is a plan view of a display device according to an example embodiment of the present disclosure.

FIG. 2 is a cross-sectional view of a sub-pixel according to an example embodiment of the present disclosure.

FIGS. 3A and 3B are plan views of a hole area of a display device according to an example embodiment of the present disclosure.

FIG. 4 is an example of a cross-sectional view of a display device taken along line I-I′ of FIG. 3.

FIGS. 5A to 5D are diagrams illustrating a manufacturing process according to an example embodiment of the present disclosure.

FIG. 6 is an enlarged cross-sectional view of a portion of a display device according to an example embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, regions, components, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, regions, components, sections, members, parts, regions, areas, portions, and/or the like) are described using any of the terms such as “on,” “on a top of,” “upon,” “on top of,” “over,” “under,” “above,” “upper,” “below,” “lower,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, regions, components, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, region, component, section, member, part, region, area, portion, or the like) is “connected,” “coupled,” “attached,” “adhered,” “linked,” or the like to another element, the element can not only be directly connected, coupled, attached, adhered, linked, or the like to another element, but also be indirectly connected, coupled, attached, adhered, linked, or the like to another element with one or more intervening elements disposed or interposed between the elements, unless otherwise specified.

For the expression that an element (e.g., layer, film, region, component, section, member, part, region, area, portion, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phase that an element (e.g., layer, film, region, component, section, member, part, region, area, portion, or the like) is “provided,” “disposed,” “connected,” “coupled,” or the like in, on, with or to another element may be understood, for example, as that at least a portion of the element is provided, disposed, connected, coupled, or the like in, on, with or to at least a portion of another element. The phrase “through” may be understood, for example, to be at least partially through or entirely through. The phase that an element (e.g., layer, film, region, component, section, member, part, region, area, portion, or the like) “contacts,” “overlaps,” or the like with another element may be understood, for example, as that at least a portion of the element contacts, overlaps, or the like with a least a portion of another element.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, section, member, part, region, area, portion, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

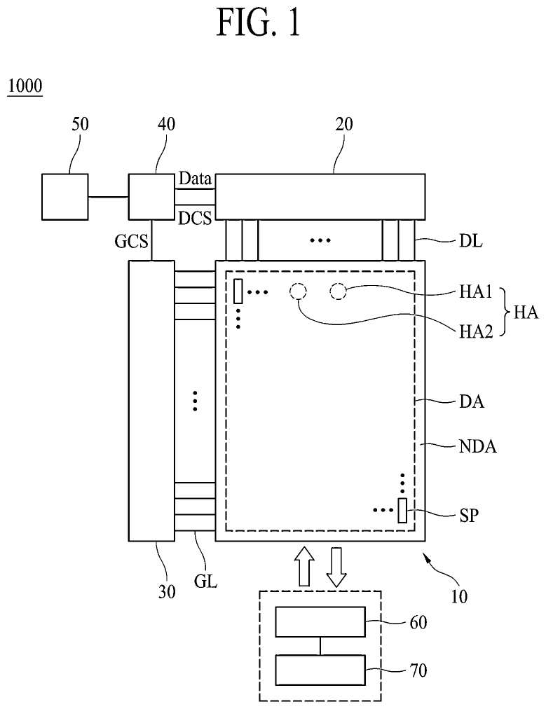

FIG. 1 is a plan view of a display device 1000 according to an example embodiment of the present disclosure.

Referring to FIG. 1, the display device 1000 according to an example embodiment of the present disclosure may include a display panel 10, a data driver 20, a gate driver 30, a display controller 40, a host system 50, a touch driver 60, and a touch controller 70.

The display panel 10 may include a display area DA and a non-display area DNA surrounding the display area DA. The display area DA is an area in which a screen may be displayed, and the non-display area NDA is an area in which a screen is not displayed.

A plurality of sub-pixels SP and a plurality of signal lines for driving the plurality of sub-pixels SP may be disposed in the display area DA. The plurality of signal lines may include a plurality of data lines DL and a plurality of gate lines GL.

Also, at least one hole area HA may be disposed in the display area DA. That is, the display area DA may surround the hole area HA. Although FIG. 1 discloses a first hole area HA1 and a second hole area HA2, it is not limited thereto. The sub-pixel SP may not be disposed in the hole area HA. Also, an electronic device may be disposed in an area overlapping the hole area HA. For example, a photographing device such as a camera may be disposed below the first hole area HA1, and a detection sensor such as a proximity sensor and an illuminance sensor may be disposed below the second hole area HA2, but is not limited thereto.

The data driver 20 is a circuit configured to drive the plurality of data lines DL, and may output data signals to the plurality of data lines DL.

The gate driver 30 is a circuit configured to drive the plurality of gate lines GL, and may output scan signals to the plurality of gate lines GL.

The display controller 40 may control the data driver 20 and the gate driver 30. The display controller 40 may supply a data driving control signal DCS to the data driver 20 to control the data driver 20. In addition, the display controller 40 may supply a gate driving control signal GCS to the gate driver 30 to control the gate driver 30.

The display controller 40 may receive input image data from the host system 50 and supply image data Data to the data driver 20 based on the input image data.

The display device 1000 according to an example embodiment of the present disclosure may provide a touch sensing function as well as an image display function. Accordingly, the display device 1000 may include a touch sensor and a touch sensing circuit. The touch sensing circuit may detect whether a touch occurs or a touch position by sensing the touch sensor.

The touch driver 60 may generate and output a touch sensing data by driving and sensing the touch sensor. In addition, the touch controller 70 may detect occurrence of the touch or detect the touch position by using the touch sensing data.

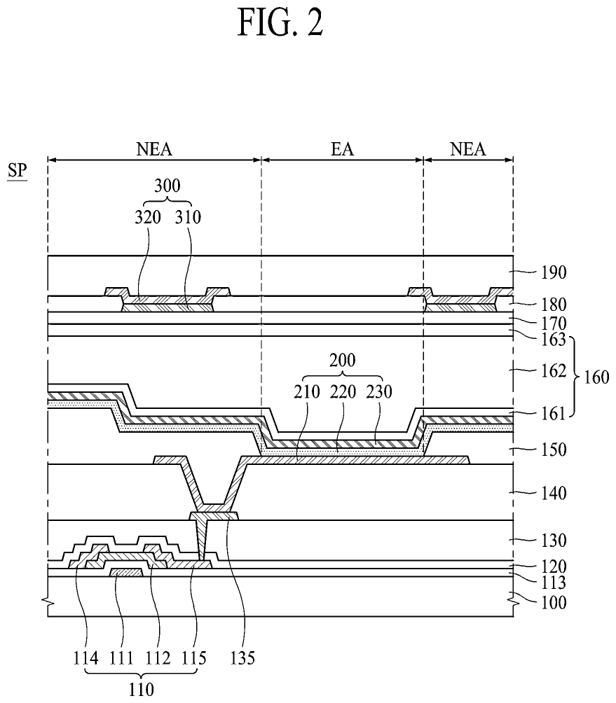

FIG. 2 is a cross-sectional view of a sub-pixel SP according to an example embodiment of the present disclosure. That is, FIG. 2 is a cross-sectional view of a partial area of the display area DA.

Referring to FIG. 2, one sub-pixel SP according to an example embodiment of the present disclosure may include a substrate 100, a thin film transistor 110, a passivation layer 120, a first planarization layer 130, a connection electrode 135, a second planarization layer 140, a bank 150, a plurality of encapsulation layers 160, a buffer layer 170, an interlayer insulating layer 180, a protective layer 190, a light emitting device 200, and a touch sensor 300.

The substrate 100 may be formed of glass or plastic, but is not limited thereto. The display device according to an example embodiment of the present disclosure may be configured in a top emission method in which the emitted light is emitted upward. Therefore, as the material of the substrate 100, not only a transparent material but also an opaque material may be used.

The thin film transistor 110 may be disposed on the substrate 100. The thin film transistor 110 may include a gate electrode 111, a semiconductor layer 112, a gate insulating layer 113, a source electrode 114, and a drain electrode 115.

The gate electrode 111 of the thin film transistor 110 may be disposed on the substrate 100. Also, the semiconductor layer 112 may be disposed on the gate electrode 111. The semiconductor layer 112 may include a poly-silicon semiconductor or an oxide semiconductor. In addition, when the semiconductor layer 112 includes the oxide semiconductor, at least one oxide of indium-gallium-zinc-oxide (IGZO), indium-zinc-oxide (IZO), indium-gallium-tin-oxide (IGTO), and indium-gallium-oxide (IGO) may be included.

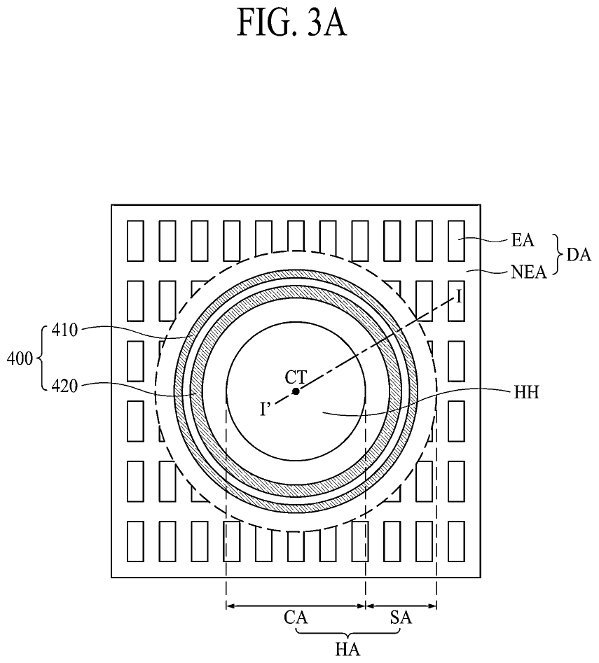

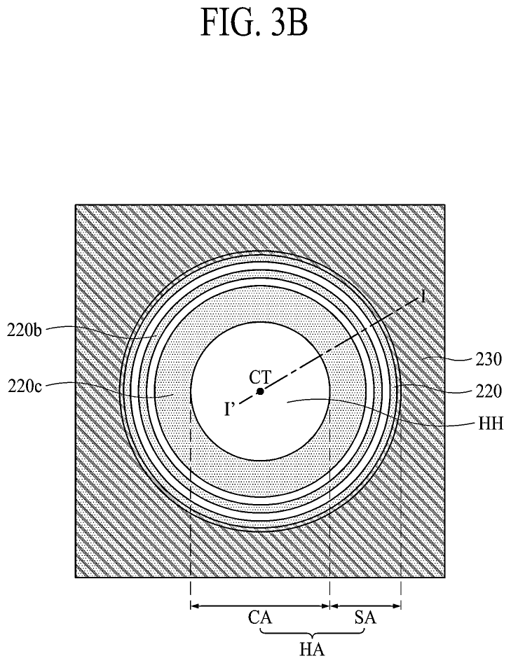

To insulate the gate electrode 111 from the semiconductor layer 112, a gate insulating layer 113 may be disposed between the gate electrode 111 and the semiconductor layer 112. The gate insulating layer 113 may include a single layer of silicon nitride (SiNx) or silicon oxide (SiOx) or multiple layers thereof. Also, although a bottom gate structure in which the semiconductor layer 112 is disposed on the gate electrode 111 is disclosed in FIG. 3, the present invention is not limited thereto. For example, a top gate structure in which the gate electrode 111 is disposed on the semiconductor layer 112 may be disclosed.

The source electrode 114 and the drain electrode 115 may be disposed on the semiconductor layer 112 while facing each other. Also, the passivation layer 120 may be disposed on the source electrode 114 and the drain electrode 115. A contact hole exposing a portion of the drain electrode 114 may be formed in the passivation layer 120. Also, the passivation layer 120 may be formed of an inorganic insulating material, such as silicon oxide (SiOx), silicon nitride (SiNx), silicon oxynitride (SiOxNy).

The first planarization layer 130 may be disposed on the thin film transistor 110, and the second planarization layer 140 may be disposed on the first planarization layer 130. The first and second planarization layers 130 and 140 may compensate for a step difference caused by the thin film transistor 110 to planarize an upper region of the thin film transistor 110. Furthermore, the first and second planarization layers 130 and 140 may be formed of an organic insulating material such as an acrylic resin, an epoxy resin, a phenolic resin, a polyamide resin, or a polyimide resin.

The light emitting device 200 may be disposed on the second planarization layer 140. The light emitting device 200 may include a first electrode 210, a light emitting layer 220, and a second electrode 230.

The first electrode 210 is disposed on the second planarization layer 140 and may function as an anode of the display device. The first electrode 210 may be electrically connected with the drain electrode 115 of the thin film transistor 110 through the connection electrode 135 disposed on the first planarization layer 130.

The first electrode 210 may include a transparent conductive material such as an indium tin oxide (ITO) or an indium zinc oxide (IZO). Alternatively, the first electrode 210 may include a metal material such as aluminum (Al), silver (Ag), copper (Cu), molybdenum (Mo), titanium (Ti), tungsten (W), or chromium (Cr), or an alloy thereof. Also, although illustrated as a single layer, the first electrode 210 may be formed of multiple layers.

The bank 150 may be disposed on the planarization layer 140 and the first electrode 210. The bank 150 may define an emitting area EA and a non-emitting area NEA. That is, the area in which the bank 150 is not disposed may become the emitting area EA, and the area in which the bank 150 is disposed may become the non-emitting area NEA.

The bank 150 may include an organic insulating material such as an acrylic resin, an epoxy resin, a phenolic resin, a polyamide resin, a polyimide resin, or the like. Alternatively, the bank 750 may include an inorganic insulating material such as silicon oxide (SiOx), silicon nitride (SiNx), silicon oxynitride (SiOxNy). Also, the bank 150 may include a black dye in order to absorb light incident from the outside.

The light emitting layer 220 may be disposed on the first electrode 210. The light emitting layer 220 may also be disposed on the bank 150. That is, the light emitting layer 220 may also be disposed in the emitting area EA and the non-emitting area NEA.

The light emitting layer 220 may include a hole transporting layer, an organic emission layer, and an electron transporting layer. In this case, when a voltage is applied to the first electrode 210 and the second electrode 230, holes and electrons move to the organic emission layer through the hole transporting layer and the electron transporting layer, respectively, and may be combined with each other in the organic emission layer to emit light.

The light emitting layer 220 may emit white light. To this end, the light emitting layer 220 may include a plurality of stacks emitting light of different colors.

The second electrode 230 may be disposed on the light emitting layer 220. The second electrode 230 may function as a cathode of the display device. Like the light emitting layer 220, the second electrode 230 may be disposed in the emitting area EA and the non-emitting area NEA.

Since the display device according to an example embodiment of the present disclosure is configured in a top emission type, the second electrode 230 may include a transparent conductive material such as an indium tin oxide (ITO) or an indium zinc oxide (IZO) to transmit the light emitted from the light emitting layer 220 upward.

The plurality of encapsulation layers 160 may be disposed on the light emitting device 200. Also, the plurality of encapsulation layers 160 may include a first encapsulation layer 161, a second encapsulation layer 162 and a third encapsulation layer 163.

The first encapsulation layer 161 may be disposed on the second electrode 230 of the light emitting device 200. Also, the first encapsulation layer 161 may include an inorganic insulating material such as silicon oxide (SiOx), silicon nitride (SiNx), silicon oxynitride (SiOxNy), and the like.

The second encapsulation layer 162 may be disposed on the first encapsulation layer 161. The second encapsulation layer 162 may alleviate stress generated in each layer when the display device is bent, and may improve planarization performance of the encapsulation layer 160. Also, the second encapsulation layer 162 may have the thickest thickness among the first encapsulation layer 161, the second encapsulation layer 162 and the third encapsulation layer 163. The second encapsulation layer 162 may include an organic insulating material such as an acrylic resin, an epoxy resin, a phenolic resin, a polyamide resin, or a polyimide resin.

The third encapsulation layer 163 may be disposed on the second encapsulation layer 162. Also, the third encapsulation layer 163 may include an inorganic insulating material such as silicon oxide (SiOx), silicon nitride (SiNx), silicon oxynitride (SiOxNy).

The touch sensor 300 may be disposed on the third encapsulation layer 163. Also, the touch sensor 300 may include a bridge electrode 310 and a plurality of touch electrodes 320.

During a process of manufacturing the touch sensor 300, an etchant used in the process of manufacturing or external moisture may penetrate into the display device 1000. In particular, the etchant or the external moisture may penetrate into the light emitting layer 220 of the light emitting device 200 including an organic material. To prevent penetration, the buffer layer 170 may be disposed between the touch sensor 300 and the third encapsulation layer 163. That is, the buffer layer 170 may prevent damage to the light emitting layer 220 that is vulnerable to the etchant or moisture.

The buffer layer 170 may include an organic insulating material such as an acrylic resin, an epoxy resin, a phenolic resin, a polyamide resin, or a polyimide resin. Accordingly, the buffer layer 170 may have planarization performance, and thus, even if the display device is bent, damage to the touch sensor 300 disposed on the buffer layer 170 may be minimized.

The bridge electrode 310 and the interlayer insulating layer 180 may be disposed on the buffer layer 170. The interlayer insulating layer 180 may cover an end of the bridge electrode 310 and expose a part of an upper surface of the bridge electrode 310.

A plurality of touch electrodes 320 are disposed on the interlayer insulating layer 180 and may be spaced apart from each other. Some of the plurality of touch electrodes 320 may be electrically connected with each other through the bridge electrode 310. For example, when the plurality of touch electrodes 320 include a first electrode and a second touch electrode, each of the first and second touch electrodes may be disposed to be in contact with an upper surface of the bridge electrode 310. Accordingly, the first and second touch electrodes may be electrically connected with each other through the bridge electrode 310.

The protective layer 190 may be disposed to cover the touch sensor 300 and may protect the touch sensor 300. Furthermore, the protective layer 190 may include an organic insulating material such as an acrylic resin, an epoxy resin, a phenolic resin, a polyamide resin, or a polyimide resin.

FIGS. 3A and 3B are plan views of a hole area HA of a display device 1000 according to an example embodiment of the present disclosure. The hole area HA of FIGS. 3A and 3B may correspond to one of the first and second hole areas HA1 and HA2 shown in FIG. 1.

As described above in FIG. 1, the emitting area EA and the non-emitting area NEA may be disposed in the display area DA. Also, the hole area HA may be disposed in the display area DA. That is, the display area DA may surround the hole area HA. The sub-pixel SP may not be disposed in the hole area HA. Also, the hole area HA may include a central area CA and a peripheral area SA.

Referring to FIG. 3A, the central area CA may include a hole HH. The hole HH may have a circular shape having a constant radius from a hole center CT, but is not limited thereto. For example, the hole HH may be a polygon.

The peripheral area SA may be disposed to surround the central area CA. The peripheral area SA may include a plurality of dams 400. Each of the plurality of dams 400 may have a closed curve shape surrounding the central area CA. Also, each of the plurality of dams 400 may have a shape corresponding to the central area CA. For example, in FIG. 3A, since the central area CA has a circular shape, the plurality of dams 400 may have a ring shape having a constant radius from the hole center CT.

A plurality of dams 400 may include a first dam 410 and a second dam 420. Also, the first and second dams 410 and 420 may be spaced apart from each other. The second dam 420 may be closer to the central area CA than the first dam 410.

Accordingly, the hole HH of the central area CA and the sub-pixel SP of the display area DA may be completely separated through the plurality of dams 400 disposed in the peripheral area SA.

Referring to FIG. 3B, the light emitting layer 220 and the second electrode 230 may be disposed in the display area DA. As described above, the second electrode 230 may be disposed on the light emitting layer 220. Also, a partial region of the light emitting layer 220 and a partial region of the second electrode 230 may also be disposed in the peripheral area SA. In this case, an end of the light emitting layer 220 may be closer to the central area CA than an end of the second electrode 230. Also, the second electrode 230 may expose a partial region of the light emitting layer 220 without covering the end of the light emitting layer 220.

A first dummy light emitting layer 220b and a second dummy light emitting layer 220c may be disposed in the peripheral area SA. The first dummy light emitting layer 220b may be disposed on the first dam 410, and the second dummy light emitting layer 220c may be disposed on the second dam 420. The first and second dummy light emitting layers 220b and 220c may be formed in a shape corresponding to that of the first and second dams 410 and 420. For example, in FIG. 3A, since the first and second dams 410 and 420 have a ring shape having a constant radius from the hole center CT, the first and second dummy light emitting layers 220b and 220c may also have a ring shape having a constant radius from the hole center CT. Also, the second dummy light emitting layer 220c may also be disposed in the peripheral area SA adjacent to the central area CA. That is, a width of the second dummy light emitting layer 220c may be greater than that of the first dummy light emitting layer 220b.

The first and second dummy light emitting layers 220b and 220c may be formed of the same material as the light emitting layer 220. Also, the first and second dummy light emitting layers 220b and 220c may be spaced apart from each other, and may also be spaced apart from the light emitting layer 220. Accordingly, since the first and second dummy light emitting layers 220b and 220c are separated from the light emitting layer 220, even if moisture is penetrated from the outside through the hole HH, it may not penetrate into the inside of the light emitting layer 220. Accordingly, damage to the light emitting device may be minimized.

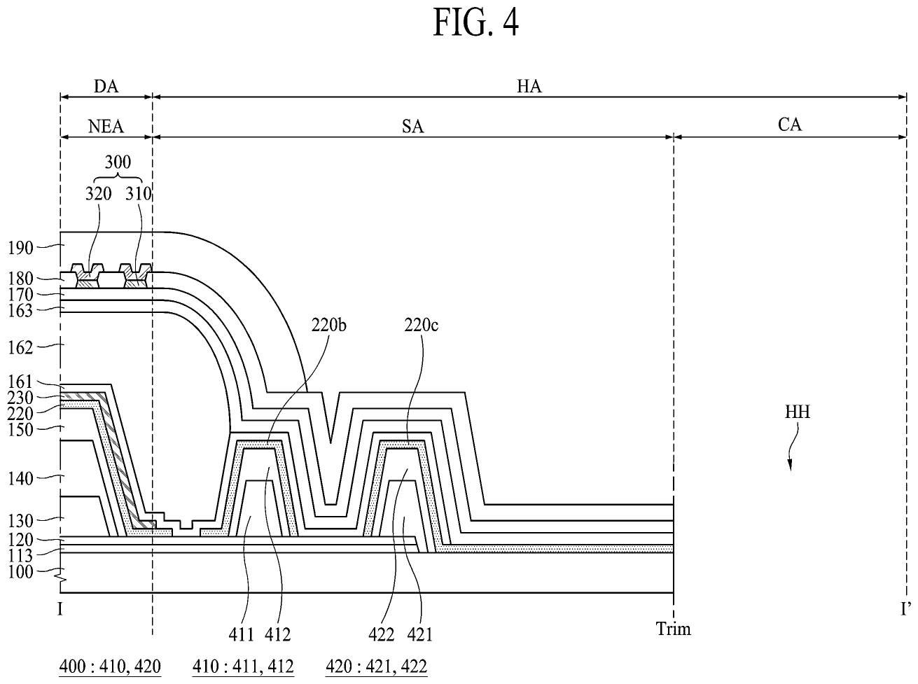

FIG. 4 is an example of a cross-sectional view of a display device taken along line I-I′ of FIG. 3. That is, FIG. 4 illustrates the non-emitting area NEA and the hole area HA of the display area DA.

As described above with reference to FIG. 2, the substrate 100, the thin film transistor 110, the passivation layer 120, the first planarization layer 130, the second planarization layer 140, the bank 150, the plurality of encapsulation layers 160, the buffer layer 170, the interlayer insulating layer 180, the protective layer 190, the light emitting device 200, and the touch sensor 300 may be disposed in the display area DA.

Referring to FIG. 4, the substrate 100 may be disposed in the display area DA and the hole area HA. Also, the substrate 100 may not be disposed in the central area CA.

The first planarization layer 130, the second planarization layer 140, the bank 150, and the light emitting device 200 may be disposed in the display area DA. In the display area DA, the second planarization layer 140 may cover an end of the first planarization layer 130, and the bank 150 may cover an end of the second planarization layer 140.

As described above in FIG. 3B, a partial region of the light emitting layer 220 and a partial region of the second electrode 230 may also be disposed in the peripheral region SA. An end of the light emitting layer 220 may be closer to the first dam 410 than an end of the second electrode 230. That is, a distance between the end of the light emitting layer 220 and the first dam 410 may be smaller than a distance between the end of the second electrode 230 and the first dam 410. Also, the second electrode 230 may expose a partial region of the light emitting layer 220 without covering the end of the light emitting layer 220.

The plurality of encapsulation layers 160 may be disposed in the display area DA and the hole area HA. Also, as described above, the plurality of encapsulation layers 160 may include the first encapsulation layer 161, the second encapsulation layer 162 and the third encapsulation layer 163.

The first encapsulation layer 161 may be disposed in the display area DA and the peripheral area SA. In the display area DA, the first encapsulation layer 161 may cover the end of the light emitting layer 220 and the end of the second electrode 230.

The second encapsulation layer 162 may be disposed in the display area DA and a boundary area between the display area DA and the peripheral area SA. That is, an end of the second encapsulation layer 162 may be disposed in the boundary area between the display area DA and the peripheral area SA. In particular, the ends of the second encapsulation layer 162 may be closer to the first dam 410 than the end of the light emitting layer 220 and the end of the second electrode 230. That is, the second encapsulation layer 162 may overlap the ends of the end of the light emitting layer 220 and the end of the second electrode 230. Also, the end of the light emitting layer 220 and the end of the second electrode 230 may be disposed between an end of the bank 150 and the end of the second encapsulation layer 162. Also, the area of the second encapsulation layer 162 may be smaller than the area of the first encapsulation layer 161.

The third encapsulation layer 163 may be disposed in the display area DA and the peripheral area SA. Also, the third encapsulation layer 163 may cover the first and second encapsulation layers 161 and 162. Particularly, in the boundary area between the display area DA and the peripheral area SA, the third encapsulation layer 163 may cover all of a top surface and a side surface of the second encapsulation layer 162. Accordingly, the third encapsulation layer 163 may minimize the penetration of external moisture into the first and second encapsulation layers 161 and 162.

Also, as described in FIG. 2, the buffer layer 170, the interlayer insulating layer 180, the protective layer 190, and the touch sensor 300 may be disposed on the third encapsulation layer 163. The touch sensor 300 and the protective layer 190 may be disposed in the display area DA, and the buffer layer 170 and the interlayer insulating layer 180 may be disposed in the display area DA and the peripheral area SA.

As described above in FIG. 3, the central area CA having the hole HH and the peripheral area SA having the plurality of dams 400 may be disposed in the hole area HA.

In the peripheral area SA, the first and second dams 410 and 420 are disposed on the substrate 100 and may be spaced apart from each other. Referring to FIG. 4, a structure in which the gate insulating layer 113 and the passivation layer 120 extend to lower portions of the first and second dams 410 and 420 is disclosed, but the present invention is not limited thereto. For example, the gate insulating layer 113 and the passivation layer 120 may extend to the lower portion of the first dam 410 and may not overlap the second dam 420. Alternatively, the gate insulating layer 113 and the passivation layer 120 may extend to the peripheral area SA adjacent to the central area CA, but are not limited thereto.

The first dam 410 may include a first lower dam 411 and a first upper dam 412 disposed on the first lower dam 411. The first upper dam 412 may cover the first lower dam 411. Also, the first lower dam 411 may be formed of the same material through the same process as the second planarization layer 140, and the first upper dam 412 may be formed of the same material through the same process as the bank 150. Like the first dam 410, the second dam 420 may include a second lower dam 421 and a second upper dam 422.

In this case, a step difference may be formed in the boundary area between the display area DA and the peripheral area SA by the first dam 410. That is, the first encapsulation layer 161 disposed on an upper surface of the first dam 410 may be disposed at a higher position than the first encapsulation layer 161 disposed on the end of the display area DA. Therefore, the second encapsulation layer 162 may be prevented from flowing to the hole area HA. Also, by arranging the second dam 420 adjacent to the first dam 410, the second encapsulation layer 162 may be further prevented from flowing to the hole area HA.

The first encapsulation layer 161, the third encapsulation layer 163, the buffer layer 170, and the interlayer insulating layer 180 may be sequentially disposed on the first and second dams 410 and 420. In a region of the peripheral area SA where the first and second dams 410 and 420 are not disposed, the third insulating layer 163, the buffer layer 170, and the interlayer insulating layer 180 may be sequentially disposed on the substrate 100. That is, in the peripheral area SA adjacent to the central area CA, the third insulating layer 163, the buffer layer 170, and the interlayer insulating layer 180 may be sequentially disposed on the substrate 100.

The hole HH may be disposed in the central area CA. The hole HH may be formed by removing the substrate 100, the first encapsulation layer 161, the third encapsulation layer 163, the buffer layer 170, and the interlayer insulating layer 180 along a trimming line Trim. The trimming line Trim may be a boundary between the peripheral area SA and the central area CA. Also, the electronic device may be disposed below the hole HH and may be disposed in an area overlapping the hole HH. For example, the electronic device may include the photographing device such as the camera or the detection sensor such as the proximity sensor or the illuminance sensor, but is not limited thereto.

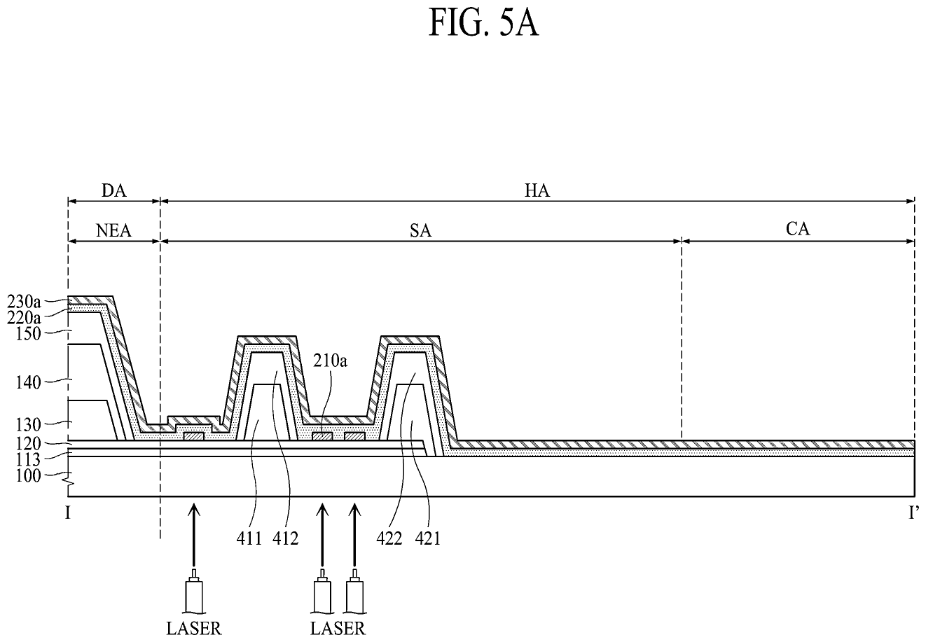

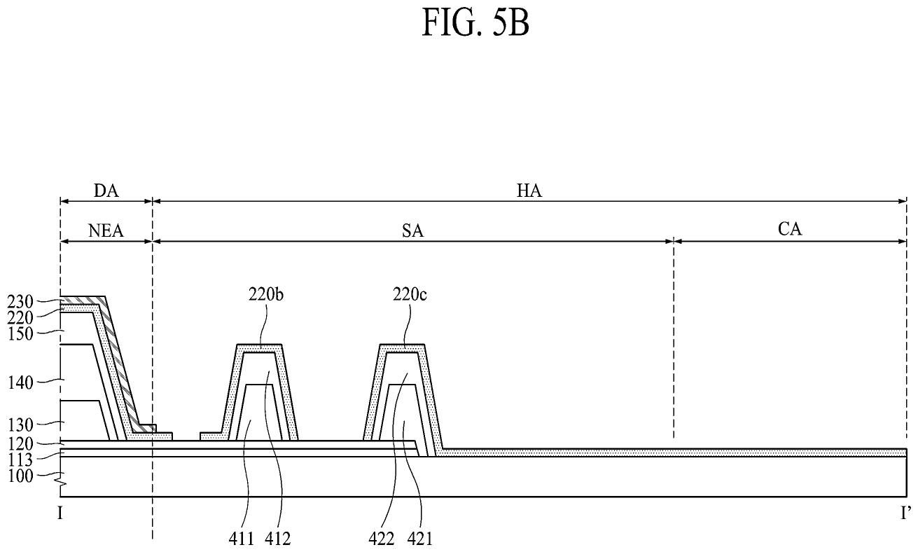

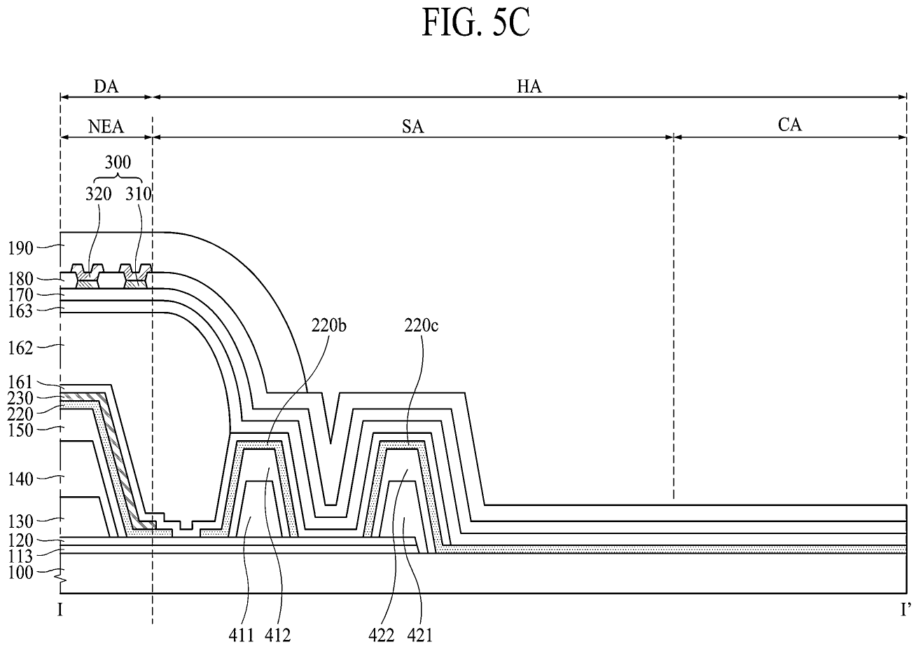

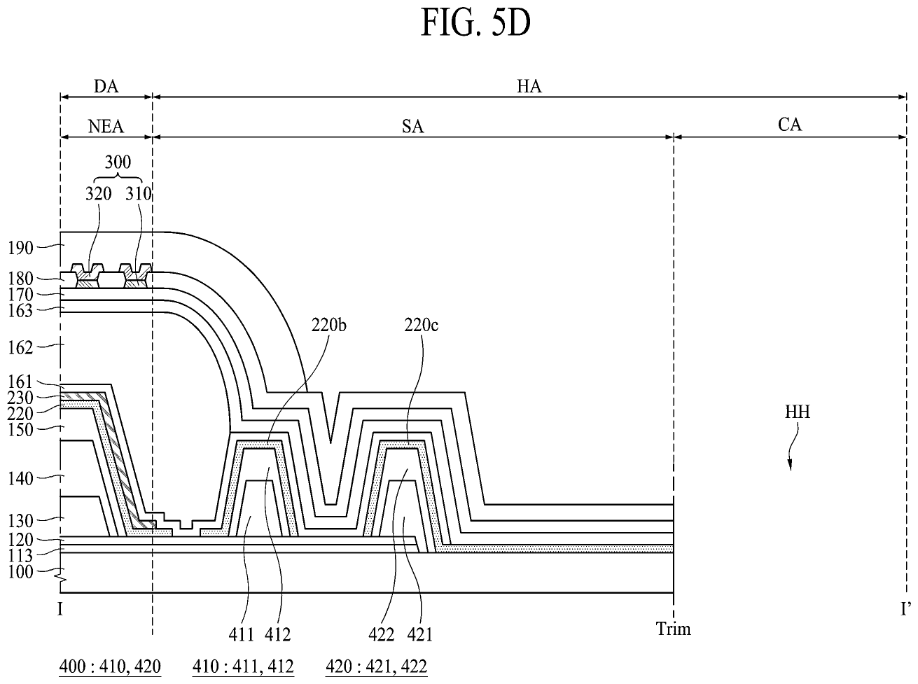

FIGS. 5A to 5D are diagrams illustrating a manufacturing process according to an example embodiment of the present disclosure.

Referring to FIG. 5A, a thin film transistor 110, a passivation layer 120, a first planarization layer 130, a second planarization layer 140, and a plurality of dams 400 may be formed on the substrate 100.

And, after a conductive material is deposited on the entire surface of the substrate 100, a partial region of the deposited conductive material may be removed to form the first electrode 210. In this case, referring to FIG. 5A, a dummy pattern 210a may be formed in the peripheral region SA together. That is, in the process of removing the deposited conductive material, the conductive material remaining in the display region DA may be used as the first electrode 210, and the conductive material remaining in the peripheral region SA may be used as the dummy pattern 210a.

The dummy pattern 210a may be formed in the peripheral area SA. Specifically, it may be formed in the peripheral area SA adjacent to the display area DA. That is, the dummy pattern 210a may be formed between the first dam 410 and the bank 150 closest to the peripheral area SA Also, the dummy pattern 210a may be formed in an area between the first and second dams 410 and 420. Referring to FIG. 5A, one dummy pattern 210a is formed between the bank 150 and the first dam 410, and the plurality of dummy patterns 210a are formed between the first and second dams 410 and 420, but the present invention is not limited thereto.

The bank 150 may be formed after the first electrode 210 and the dummy pattern 210a are formed. Also, after the bank 150 is formed, an organic material 220a and a conductive material 230a may be sequentially deposited on the entire surface of the substrate 100.

And, in order to pattern the organic material 220a and the conductive material 230a, a laser process may be performed. A laser may be irradiated to the peripheral area SA below the substrate 100. In particular, the laser may be irradiated to a position where the dummy pattern 210a is formed below the substrate 100. Since the dummy pattern 210a is made of the conductive material, heat is generated by the laser, and may be separated from an insulating layer disposed under the dummy pattern 210a. Also, heat generated from the dummy pattern 210a may be conducted to the conductive material layer 230a.

Accordingly, referring to FIG. 5B, along with the dummy pattern 210a, a partial region of the organic material layer 220a and a partial region of the conductive material layer 230a may be removed. Specifically, in the process of removing the dummy pattern 210a, a partial region of the organic material layer 220a and a partial region of the conductive material layer 230a formed to overlap the dummy pattern 210a may be removed together. Also, since the heat generated in the dummy pattern 210a is conducted to an inside of the conductive material layer 230a, a region of the conductive material layer 230a adjacent to the dummy pattern 210a may be removed together. That is, the conductive material layer 230a overlapping a top surface and a side surface of the first dam 410 and a top surface and a side surface of the second dam 420 may be removed together. Therefore, the conductive material layer 230a formed in the peripheral region SA may be completely removed through the laser process.

The organic material layer 220a remaining in the display area DA may be used as the light emitting layer 220, and the conductive material layer 230a remaining in the display area DA may be used as the second electrode 230. Accordingly, the light emitting device 200 including the first electrode 210, the light emitting layer 220, and the second electrode 230 may be formed.

Both the light emitting layer 220 and the second electrode 230 may be spaced apart from the first and second dams 410 and 420. In addition, by the laser process, on the upper region of the dummy pattern 210a, the area in which the conductive material layer 230a is removed may be larger than the area in which the organic material layer 220a is removed. Accordingly, the end of the light emitting layer 220 may be closer to the first dam 410 than the end of the second electrode 230. That is, in the peripheral area SA adjacent to the display area DA, the second electrode 230 may expose a partial area of the light emitting layer 220 without covering the end of the light emitting layer 220. Also, ends of the light emitting layer 220 and the second electrode 230 may be located between the first dam 410 and the bank 150 closest to the peripheral area SA.

Meanwhile, unlike the conductive material layer 230a, the organic material layer 220a may be less affected by the laser. Accordingly, the organic material layer 220a may remain in the peripheral area SA. In particular, the organic material layer 220a may remain on upper surfaces of the dams 410 and 420, which are positions that do not overlap the dummy pattern 210a, and may be first and second dummy light emitting layers 220b and 220c. In detail, a first dummy light emitting layer 220b may be formed on the first dam 410, and a second dummy light emitting layer 220c may be formed on the second dam 420. However, by the laser process, the first and second dummy light emitting layers 220b and 220c may be completely separated from the light emitting layer 220 in the display area DA. Accordingly, even if external moisture penetrates into the first and second dummy light emitting layers 220b and 220c, it is possible to prevent the external moisture from penetrating into the light emitting layer 220. Accordingly, damage to the light emitting layer 220 due to external moisture may be minimized.

Referring to FIG. 5C, a plurality of encapsulation layers 160, a buffer layer 170, an interlayer insulating layer 180, a protective layer 190, a light emitting device 200, and a touch sensor 300 may be formed on the light emitting device 200.

As described above, the plurality of encapsulation layers 160 may include the first encapsulation layer 161, the second encapsulation layer 162 and the third encapsulation layer 163. The first encapsulation layer 161 may be disposed in the display area DA and the peripheral area SA. The first encapsulation layer 161 may cover the light emitting device 200 in the display area DA and the dam 400 in the peripheral area SA.

After the first encapsulation layer 161 is formed, the second encapsulation layer 162 may be formed. In this case, the second encapsulation layer 162 may be prevented from flowing into the hole area HA by the first and second dams 410 and 420. Also, the second encapsulation layer 162 may overlap ends of the light emitting layer 220 and the second electrode 230. Further, the third encapsulation layer 163 may be formed to cover the entire surface of the substrate 100.

Referring to FIG. 5D, the substrate 100 may be removed along a trimming line Trim. Accordingly, a hole HH may be formed.

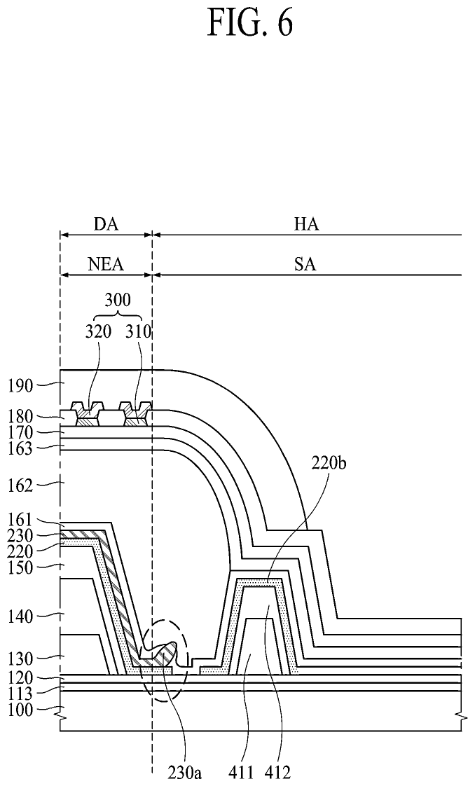

FIG. 6 is an enlarged cross-sectional view of a portion of a display device according to an example embodiment of the present disclosure. Particularly, a boundary between the display area DA and the peripheral area SA is illustrated.

Referring to FIG. 6, the second electrode 230 of the light emitting device 200 may have a protrusion 230a. Specifically, as described in FIG. 5A to FIG. 5D, the second electrode 230 may be formed by removing the conductive material 230a through the laser and the dummy pattern 210a. In this case, in the process of forming the second electrode 230, the end of the second electrode 230 may not be stably deposited on the light emitting layer 220, but may be spaced apart from the light emitting layer 220. That is, a lift-off phenomenon occurs at the end of the second electrode 230, and thus the second electrode 230 may have an unnecessary protrusion 230a. Also, since the protrusion 230a is spaced apart from the light emitting layer 220, a portion of the upper surface of the light emitting layer 220 may be exposed.

As described above, the first encapsulation layer 161, the second encapsulation layer 162 and the third encapsulation layer 163 may be formed on the second electrode 230. In this case, since the first encapsulation layer 161 is thinly deposited with the inorganic insulating material, the protrusion 230a of the second electrode 230 and the exposed ends of the light emitting layer 220 may not be covered. Alternatively, compared with the area in which the second electrode 230 is flattened, the first encapsulation layer 161 may be formed to have a relatively thin thickness on the protrusion 230a of the second electrode 230. Accordingly, the performance of the first encapsulation layer 161 that prevent the penetration of external moisture may be reduced. That is, the possibility of external moisture penetrating into the light emitting device 200 may increase.

In this case, the second encapsulation layer 162 may cover the end of the second electrode 230. Specifically, the second encapsulation layer 162 may be formed by depositing an organic insulation material relatively thicker than the first encapsulation layer 161. Accordingly, even if the protrusion 230a is formed at the end of the second electrode 230, the second encapsulation layer 162 may cover the protrusion 230a. Also, the second encapsulation layer 162 may also be disposed in the space between the protrusion 230a and the light emitting layer 220 spaced apart from the protrusion 230a. That is, the second encapsulation layer 162 may fill the space between the protrusion 230a and the light emitting layer 220 spaced apart from the protrusion 230a. Accordingly, the light emitting device 200 may be protected by the second encapsulation layer 162. Also, even if the protrusion 230a is formed at the end of the second electrode 230, the upper surface of the light emitting device 200 may be planarized by the second encapsulation layer 162, and thus the third encapsulation layer 163 may be stably deposited.

In conclusion, the present invention discloses that the second encapsulation layer 162 is formed to cover the end of the second electrode 230. In detail, in the process of patterning the conductive material 230a through the laser process, the laser may be irradiated so that the end of the second electrode 230 is disposed at a position overlapping the second encapsulation layer 162. Accordingly, even if the lift-off phenomenon occurs at the end of the second electrode 230 by the laser process, the light emitting device 200 may be stably protected through the second encapsulation layer 162. Accordingly, the penetration of external moisture into the light emitting device 200 may be minimized. Also, even if the second electrode 230 has the protrusion 230a, the upper region of the light emitting device 200 may be planarized through the second encapsulation layer 162, and thus an insulating layer and a metal layer may be stably formed on the light emitting device 200.

According to one or more aspects of the present disclosure, the following advantageous effects may be obtained.

According to one or more aspects of the present disclosure, the plurality of light conversion layers may be formed so that light efficiency may be improved, and reflectance due to external light may be reduced.

It will be apparent to those skilled in the art that the present disclosure described above is not limited by the above-described embodiments and the accompanying drawings and that various substitutions, modifications and variations can be made in the present disclosure without departing from the scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display device, comprising:
a substrate;
a hole area;
a display area surrounding the hole area;
a light emitting device disposed in the display area on the substrate;
a plurality of encapsulation layers disposed on the light emitting device; and
a first dam and a second dam disposed in the hole area on the substrate, the first dam and the second dam spaced apart from each other,
wherein:
the light emitting device includes a first electrode disposed on the substrate, a light emitting layer disposed on the first electrode, and a second electrode disposed on the light emitting layer; and
an end of the second electrode overlaps at least one of the plurality of encapsulation layers and is spaced apart from the first dam and the second dam.

2. The display device of claim 1,
wherein the display area includes:
an emitting area in which the light emitting device is disposed; and
a non-emitting area surrounding the emitting area,
wherein the non-emitting area includes a bank disposed on the first electrode, and
wherein an end of the light emitting layer and an end of the second electrode are disposed between the bank and the first dam.

3. The display device of claim 2, wherein compared to the end of the second electrode, the end of the light emitting layer is closer to the first dam than.

4. The display device of claim 1, wherein the plurality of encapsulation layers include:
a first encapsulation layer disposed on the light emitting device and including an inorganic insulating material;
a second encapsulation layer disposed on the first encapsulation layer and including an organic insulating material; and
a third encapsulation layer disposed on the second encapsulation layer and including an inorganic insulating material.

5. The display device of claim 4, wherein the end of the second electrode overlaps the second encapsulation layer.

6. The display device of claim 4, wherein the second electrode includes a protrusion protruding from the end of the second electrode, the protrusion spaced apart from the light emitting layer.

7. The display device of claim 6, wherein the second encapsulation layer covers the protrusion.

8. The display device of claim 7, wherein the second encapsulation layer fills a space between the protrusion and the light emitting layer.

9. The display device of claim 1, wherein the hole area includes a first dummy light emitting layer and a second dummy light emitting layer, and
the first dummy light emitting layer and the second dummy light emitting layer are made of a material that is same as a material of the light emitting layer.

10. The display device of claim 9, wherein the first dummy light emitting layer is disposed on an upper portion of the first dam,
the second dummy light emitting layer is disposed on an upper portion of the second dam, and
the first dummy light emitting layer and the second dummy light emitting layer are spaced apart from each other.

11. The display device of claim 10, wherein the light emitting layer is spaced apart from the first dummy light emitting layer and the second dummy light emitting layer.

12. The display device of claim 4,
wherein the hole area includes:
a central area having a hole; and
a peripheral area surrounding the central area,
wherein the hole is an area in which a portion of the substrate is removed, and
wherein the first dam and the second dam are disposed in the peripheral area.

13. The display device of claim 12, wherein compared to the second dam, the first dam is closer to the display area.

14. The display device of claim 12, wherein the first encapsulation layer and the third encapsulation layer are disposed in the peripheral area and cover the first dam and the second dam.

15. A display device, comprising:
a hole area;
a display area surrounding the hole area; and
a central area having a hole and a peripheral area surrounding the central area, in the hole area,
wherein:
the peripheral area includes a first dam and a second dam disposed on a substrate, the first dam and the second dam surrounding the hole;
a first dummy light emitting layer disposed on the first dam; and
a second dummy light emitting layer disposed on the second dam.

16. The display device of claim 15, wherein the first dam and the second dam have a closed curve shape surrounding the central area and are spaced apart from each other.

17. The display device of claim 16, wherein compared to the second dam, the first dam is closer to the display area.

18. The display device of claim 16, wherein the first dummy light emitting layer has a shape corresponding to that of the first dam, and
the second dummy light emitting layer has a shape corresponding to that of the second dam.

19. The display device of claim 18, wherein the second dummy light emitting layer extends to the peripheral area adjacent to the central area.

20. The display device of claim 19, wherein the display area includes a light emitting layer disposed on the substrate,
a partial area of the light emitting layer is disposed in the peripheral area, and
the light emitting layer is spaced apart from the first dummy light emitting layer and the second dummy light emitting layer.
